(19) United States
(12) Patent Application Publication
(10) Pub. No.: US 2024/0268130 A1
(43) Pub. Date: Aug. 8, 2024

(54) SEMICONDUCTOR DEVICE

(71) Applicant: SAMSUNG ELECTRONICS CO., LTD., Suwon-si (KR)

(72) Inventors: Hyungeun CHOI, Suwon-si (KR); Kiseok LEE, Suwon-si (KR)

(21) Appl. No.: 18/374,718

(22) Filed: Sep. 29, 2023

(30) Foreign Application Priority Data
Feb. 2, 2023 (KR) 10-2023-0014440

(51) Int. Cl. H10B 80/00; H01L 23/00; H01L 25/00; H01L 25/065; H01L 25/18

(52) U.S. Cl. CPC H10B 80/00; H01L 24/08; H01L 24/80; H01L 25/0657; H01L 25/18; H01L 25/50; H01L 2224/08146; H01L 2224/80895; H01L 2224/80896; H01L 2225/06541; H01L 2924/1431; H01L 2924/1436

(57) ABSTRACT

Disclosed are semiconductor devices and their fabrication methods. The semiconductor device includes a lower bonding structure that includes a lower substrate, a lower dielectric structure on the lower substrate, and a transistor between the lower substrate and the lower dielectric structure, an upper bonding structure that includes an upper dielectric structure on the lower dielectric structure, an upper substrate on the upper dielectric structure, and a memory cell structure between the upper substrate and the upper dielectric structure, a connection structure on the upper bonding structure, and a first through via that electrically connects the transistor to the memory cell structure. The transistor overlaps the memory cell structure. The first through via penetrates the upper substrate and the upper dielectric structure.

### CROSS-REFERENCE TO RELATED APPLICATION

This U.S. nonprovisional application claims priority under 35 U.S.C § 119 to Korean Patent Application No. 10-2023-0014440 filed on Feb. 2, 2023 in the Korean Intellectual Property Office, the disclosure of which is hereby incorporated by reference in its entirety.

### BACKGROUND

### 1 Field

Embodiments relate to a semiconductor device, and more particularly, to a semiconductor device including a through via.

### 2. Description of the Related Art

A semiconductor device includes an integrated circuit consisting of metal oxide semiconductor field effect transistors (MOSFETs). As size and design rule of the semiconductor device have gradually decreased, sizes of the MOSFETs are also being increasingly scaled down. Scaling down MOSFETs could deteriorate the operating characteristics of a semiconductor device. Accordingly, research has been variously developed to manufacture a semiconductor device having excellent performances while overcoming limitations due to integration of the semiconductor device.

### SUMMARY

According to some embodiments, a semiconductor device may include a lower bonding structure that includes a lower substrate, a lower dielectric structure on the lower substrate, and a transistor between the lower substrate and the lower dielectric structure; an upper bonding structure that includes an upper dielectric structure on the lower dielectric structure, an upper substrate on the upper dielectric structure, and a memory cell structure between the upper substrate and the upper dielectric structure, a connection structure on the upper bonding structure and a first through via that electrically connects the transistor to the memory cell structure. The transistor may overlap the memory cell structure. The first through via may penetrate the upper substrate and the upper dielectric structure.

According to some embodiments, a semiconductor device may include a lower bonding structure that includes a lower substrate, a lower dielectric structure on the lower substrate, a lower conductive structure in the lower dielectric structure, a first transistor between the lower substrate and the lower dielectric structure, an upper bonding structure that includes an upper dielectric structure on the lower dielectric structure, an upper substrate on the upper dielectric structure, and a memory cell structure between the upper substrate and the upper dielectric structure, the memory cell structure including a bit line, a first through via that penetrates the upper substrate and the upper dielectric structure and is in contact with the lower conductive structure, a second through via that penetrates the upper substrate and is in contact with the bit line; and a bit-line connection pattern in contact with the first through via and the second through via.

According to some embodiments, a semiconductor device may include a lower substrate, a lower dielectric structure on the lower substrate, a transistor between the lower substrate and the lower dielectric structure, a lower conductive structure in the lower dielectric structure and connected to the transistor, an upper dielectric structure on the lower dielectric structure, an upper substrate on the upper dielectric structure, a memory cell structure between the upper substrate and the upper dielectric structure, the memory cell structure including a bit line, a connection dielectric structure on the upper substrate, a bit-line connection pattern in the connection dielectric structure, a first through via that connects the lower conductive structure to the bit-line connection pattern and penetrates the upper substrate and the upper dielectric structure, and a second through via that connects the bit line to the bit-line connection pattern and penetrates the upper substrate. The bit-line connection pattern including an extension part that extends in a first direction and a connection part that extends in a direction intersecting the first direction and the transistor may overlap the memory cell structure.

According to some embodiments, a method of fabricating a semiconductor device may include forming on an upper substrate a memory cell structure including a bit line; forming an upper dielectric structure that covers the memory cell structure; forming a transistor on a lower substrate; forming a lower dielectric structure that covers the transistor; bonding the upper dielectric structure to the lower dielectric structure; and forming a through via that penetrates the upper substrate and the upper dielectric structure. The transistor may overlap the memory cell structure.

### BRIEF DESCRIPTION OF DRAWINGS

Features will become apparent to those of skill in the art by describing in detail exemplary embodiments with reference to the attached drawings in which:

FIG. 1A illustrates a plan view showing a semiconductor device according to some embodiments.

FIG. 1B illustrates an enlarged view showing section A of FIG. 1A.

FIG. 1C illustrates an enlarged view showing section B of FIG. 1B.

FIG. 1D illustrates a cross-sectional view taken along line I-I′ of FIG. 1C.

FIG. 1E illustrates a cross-sectional view showing a first peripheral region of FIG. 1A.

FIG. 1F illustrates an enlarged view showing section C of FIG. 1D.

FIGS. 2A, 2B, 3A, 3B, 4A, 4B, 5A, and 5B illustrate cross-sectional views showing a method of fabricating a semiconductor device according to some embodiments.

FIG. 6 illustrates an enlarged cross-sectional view showing a semiconductor device according to some embodiments.

FIG. 7 illustrates an enlarged cross-sectional view showing a semiconductor device according to some embodiments.

FIG. 8 illustrates an enlarged cross-sectional view showing a semiconductor device according to some embodiments.

FIG. 9 illustrates a plan view showing a bit-line connection structure of a semiconductor device according to some embodiments.

FIG. 10 illustrates a plan view showing a bit-line connection structure of a semiconductor device according to some embodiments.

FIG. 11 illustrates a plan view showing a bit-line connection structure of a semiconductor device according to some embodiments.

FIG. 12 illustrates a plan view showing a bit-line connection structure of a semiconductor device according to some embodiments.

FIG. 13 illustrates an enlarged cross-sectional view showing a semiconductor device according to some embodiments.

FIGS. 14A and 14B illustrate cross-sectional views showing a memory cell structure according to some embodiments.

### DETAILED DESCRIPTION

A semiconductor device according to some embodiments will be discussed in conjunction with the accompanying drawings.

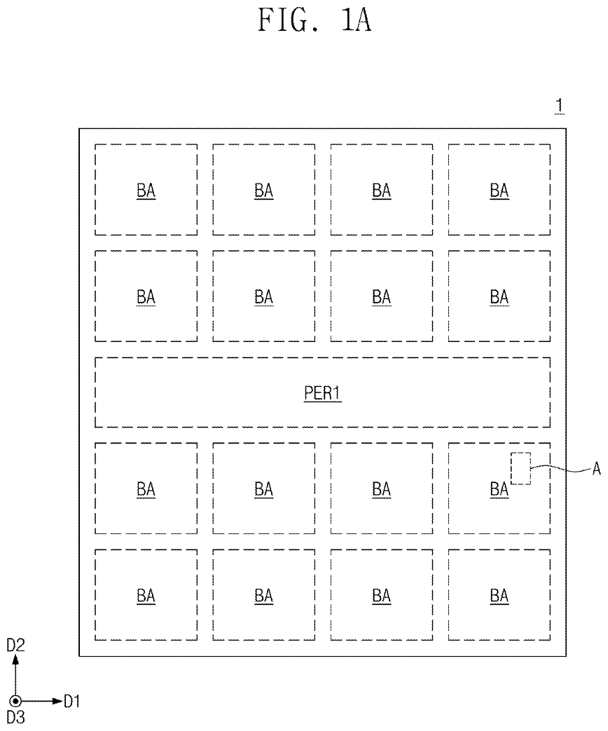

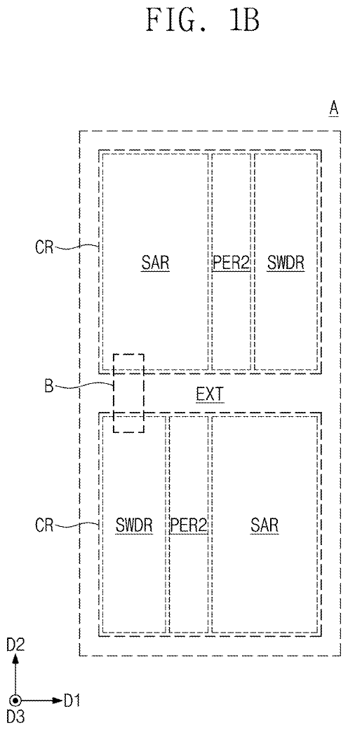

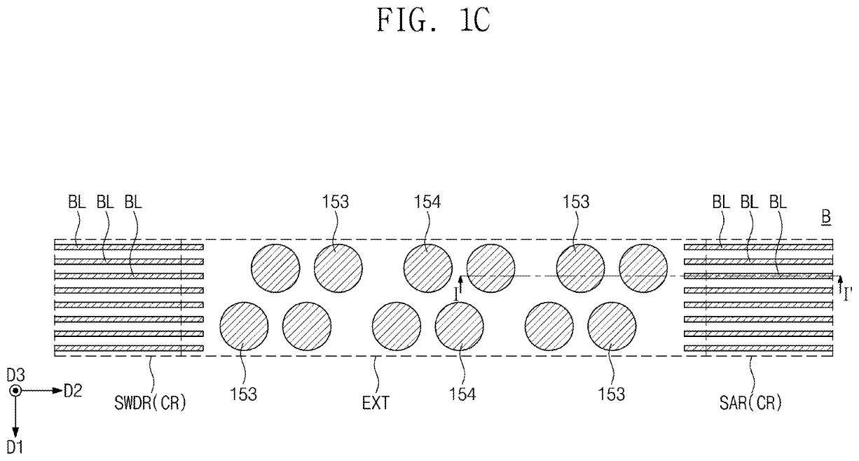

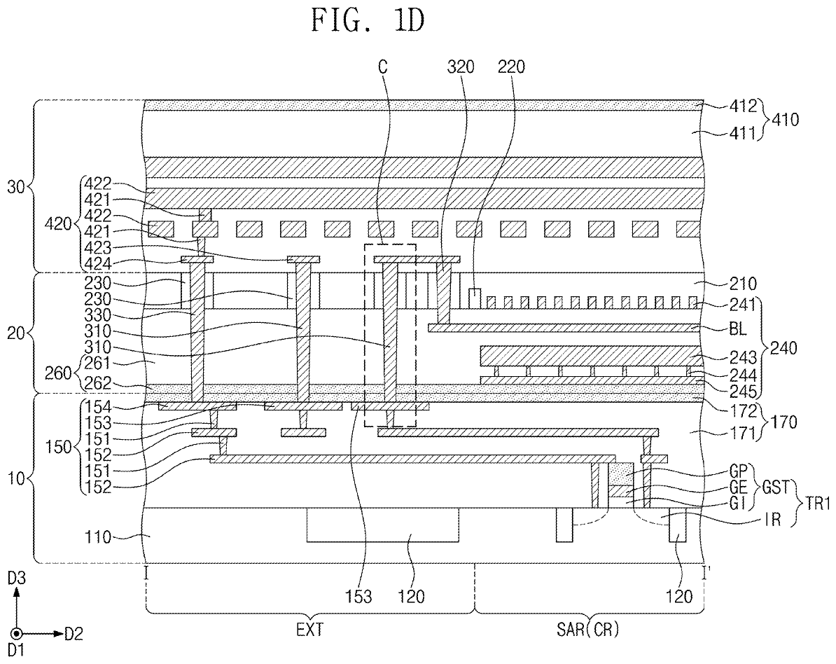

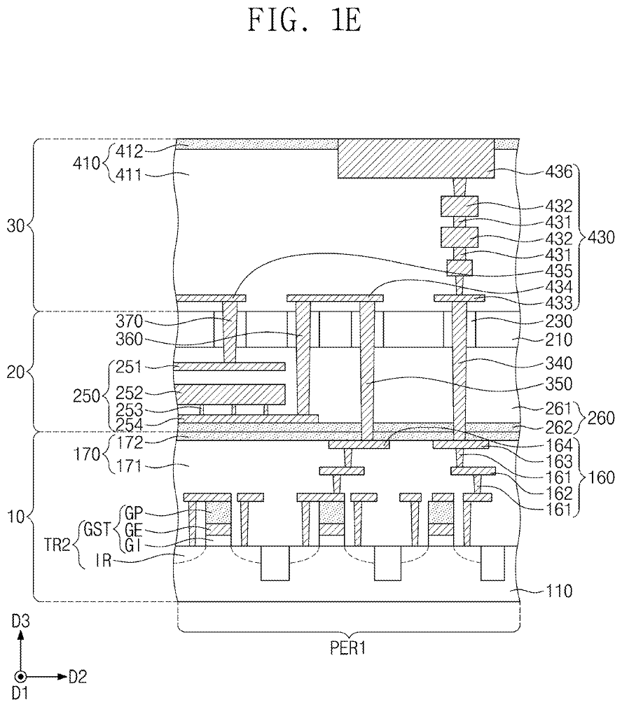

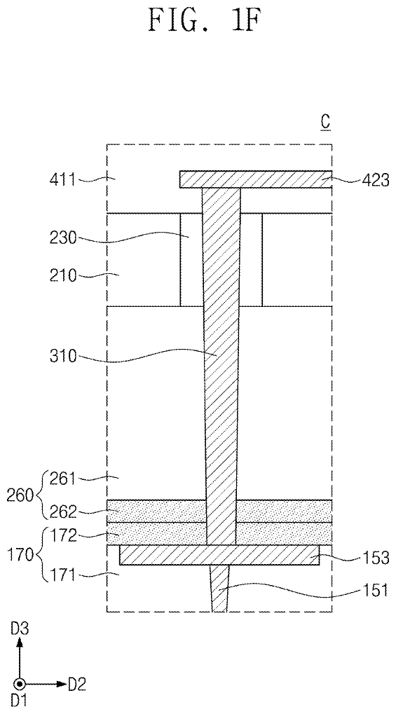

FIG. 1A illustrates a plan view showing a semiconductor device according to some embodiments. FIG. 1B illustrates an enlarged view showing section A of FIG. 1A. FIG. 1C illustrates an enlarged view showing section B of FIG. 1B. FIG. 1D illustrates a cross-sectional view taken along line I-I′ of FIG. 1C. FIG. 1E illustrates a cross-sectional view showing a first peripheral region of FIG. 1A. FIG. 1F illustrates an enlarged view showing section C of FIG. 1D.

Referring to FIGS. 1A and 1B, a semiconductor device 1 may include a plurality of banks BA and a first peripheral region PER1. The first peripheral region PER1 may be disposed between the banks BA. The first peripheral region PER1 may be provided thereon with peripheral circuits for input/output of data, command, or power/ground.

Each of the banks BA may include cell block regions CR and an extension region EXT between the cell block regions CR. Each of the cell block regions CR may include a sense amplifier region SAR, a second peripheral region PER2, and a sub-word line driver region SWDR. The sense amplifier region SAR may be provided thereon with sense amplifiers. The sub-word line driver region SWDR may be provided thereon with sub-word line drivers.

Referring to FIGS. 1C, 1D, 1E, and 1F, the semiconductor device 1 may include a lower bonding structure 10, an upper bonding structure 20 on the lower bonding structure 10, and a connection structure 30 on the upper bonding structure 20.

The lower bonding structure 10 may include a lower substrate 110, first device isolation layers 120, first transistors TR1, second transistors TR2, first lower conductive structures 150, second lower conductive structures 160, and a lower dielectric structure 170.

The lower substrate 110 may have a plate shape that extends along a plane defined by a first direction D1 and a second direction D2. The first direction D1 and the second direction D2 may intersect each other. For example, the first direction D1 and the second direction D2 may be horizontal directions that are orthogonal to each other. In some embodiments, the lower substrate 110 may be a semiconductor substrate. For example, the lower substrate 110 may include silicon, germanium, silicon-germanium, gallium-phosphorus, or gallium-arsenic. In some embodiments, the lower substrate 110 may be a silicon-on-insulator (SOI) substrate or a germanium-on-insulator (GOI) substrate.

The first device isolation layers 120 may be provided in the lower substrate 110. The first device isolation layers 120 may include a dielectric material.

The first transistors TR1 and the second transistors TR2 may be provided on the lower substrate 110. The first transistors TR1 and the second transistors TR2 may be disposed between the lower substrate 110 and the lower dielectric structure 170. Each of the first and second transistors TR1 and TR2 may include impurity regions IR, and may also include a channel and a gate structure GST between the impurity regions IR.

The lower substrate 110 may be implanted with impurities to form the impurity regions IR. The gate structure GST may include a gate dielectric layer GI, a gate electrode GE on the gate dielectric layer GI, and a gate capping layer GP on the gate electrode GE. The gate dielectric layer GI and the gate capping layer GP may include a dielectric material. The gate electrode GE may include a conductive material.

The first transistor TR1 may be disposed on the sense amplifier region SAR of the cell block region CR. The first transistor TR1 may be a transistor that constitutes the sense amplifier. The second transistor TR2 may be disposed on the first peripheral region PER1.

The lower dielectric structure 170 may cover the first and second transistors TR1 and TR2. The lower dielectric structure 170 may be provided on the lower substrate 110. The lower dielectric structure 170 may include a first lower dielectric layer 171 on the lower substrate 110 and a second lower dielectric layer 172 on the first lower dielectric layer 171. The first lower dielectric layer 171 and the second lower dielectric layer 172 may include different dielectric materials from each other. For example, the first lower dielectric layer 171 may include a SiO₂ layer, and the second lower dielectric layer 172 may include a SiCN layer and a SiCON layer.

In some embodiments, the first lower dielectric layer 171 may be a multiple dielectric layer including a plurality of dielectric layers. In some embodiments, the first lower dielectric layer 171 and the second lower dielectric layer 172 may include the same dielectric material. For example, the first and second lower dielectric layers 171 and 172 may include a SiO₂ layer.

The first lower conductive structures 150 and the second lower conductive structures 160 may be disposed in the first lower dielectric layer 171 of the lower dielectric structure 170. The first lower conductive structures 150 may be electrically connected to the first transistor TR1. The first lower conductive structure 150 may include first lower contacts 151, first lower conductive lines 152, first pads 153, and second pads 154. A conductive material may be included in the first lower contacts 151, the first lower conductive lines 152, the first pads 153, and the second pads 154 of the first lower conductive structures 150.

The first pads 153 and the second pads 154 may be disposed in the extension region EXT. At least a portion of the first lower conductive lines 152 may extend from the extension region EXT toward the sense amplifier region SAR. The first pads 153 and the second pads 154 may be disposed at the top of the first lower conductive structures 150. The first lower contacts 151 and the first lower conductive lines 152 may be located at a level lower than that of the first pads 153 and the second pads 154. The first pad 153 may be electrically connected to the first transistor TR1 through the first lower contact 151 and the first lower conductive line 152. The second pad 154 may be electrically connected to the first transistor TR1 through the first lower contact 151 and the first lower conductive line 152.

The first and second pads 153 and 154 may have top surfaces that are in contact with a bottom surface of the second lower dielectric layer 172. The top surfaces of the first and second pads 153 and 154 may be coplanar with a top surface of the first lower dielectric layer 171. The first pad 153 may be disposed closer than the second pad 154 to the sense amplifier region SAR. The first and second pads 153 and 154 may each have a circular shape when viewed in a plan view.

The second lower conductive structures 160 may be electrically connected to the second transistors TR2. The second lower conductive structure 160 may include second lower contacts 161, second lower conductive lines 162, a third pad 163, and a fourth pad 164. A conductive material may be included in the second lower contacts 161, the second lower conductive lines 162, the third pad 163, and the fourth pad 164 of the second lower conductive structure 160. The first peripheral region PER1 may be provided thereon with the second lower contacts 161, the second lower conductive lines 162, the third pad 163, and the fourth pad 164 of the second lower conductive structures 160.

The third pad 163 and the fourth pad 164 may be disposed at the top of the second lower conductive structures 160. The second lower contacts 161 and the second lower conductive lines 162 may be located at a level lower than that of the third pad 163 and the fourth pad 164. The third pad 163 and the fourth pad 164 may be electrically connected to the second lower contact 161 and the second lower conductive line 162.

The third and fourth pads 163 and 164 may have top surfaces that are in contact with a bottom surface of the second lower dielectric layer 172. The top surfaces of the third and fourth pads 163 and 164 may be coplanar with the top surfaces of the first lower dielectric layer 171. The third and fourth pads 163 and 164 may each have a circular shape when viewed in a plan view.

The upper bonding structure 20 may include an upper substrate 210, a second device isolation layer 220, dielectric patterns 230, a memory cell structure 240, a power capacitor structure 250, and an upper dielectric structure 260. The upper substrate 210 may have a plate shape that extends along a plane defined by the first direction D1 and the second direction D2. In some embodiments, the upper substrate 210 may be a semiconductor substrate. The upper substrate 210 may include, for example, silicon, germanium, silicon-germanium, gallium-phosphorus, or gallium-arsenic. In some embodiments, the upper substrate 210 may be a silicon-on-insulator (SOI) substrate or a germanium-on-insulator (GOI) substrate.

The second device isolation layer 220 may be provided in the upper substrate 210. The second device isolation layer 220 may include a dielectric material.

The upper dielectric structure 260 may be provided between the upper substrate 210 and the lower dielectric structure 170. The upper dielectric structure 260 may cover the memory cell structure 240 and the power capacitor structure 250. The memory cell structure 240 and the power capacitor structure 250 may be disposed between the upper substrate 210 and the upper dielectric structure 260. The upper dielectric structure 260 may be provided on the lower dielectric structure 170. The upper dielectric structure 260 may include a first upper dielectric layer 261 and a second upper dielectric layer 262. The second upper dielectric layer 262 may be provided on the second lower dielectric layer 172, and the first upper dielectric layer 261 may be provided on the second upper dielectric layer 262. The first and second upper dielectric layers 261 and 262 may include different dielectric materials from each other. For example, the first upper dielectric layer 261 may include a SiO₂ layer, and the second upper dielectric layer 262 may include a SiCN layer and a SiCON layer.

In some embodiments, the first upper dielectric layer 261 may be a multiple dielectric layer including a plurality of dielectric layers. In some embodiments, the first and second upper dielectric layers 261 and 262 may include the same dielectric material. For example, the first and second upper dielectric layers 261 and 262 may include a SiO₂ layer.

When the second lower dielectric layer 172 and the second upper dielectric layer 262 include a SiO₂ layer, the SiO₂ layer of the second lower dielectric layer 172 may be bonded to the SiO₂ layer of the second upper dielectric layer 262. When the second lower dielectric layer 172 and the second upper dielectric layer 262 include a SiCN layer and a SiCON layer, the SiCON layer of the second lower dielectric layer 172 may be bonded to the SiCON layer of the second upper dielectric layer 262.

The dielectric patterns 230 may penetrate the upper substrate 210. The dielectric pattern 230 may have a top surface that is coplanar with the top surface of the upper substrate 210. The dielectric pattern 230 may have a bottom surface that is coplanar with the bottom surface of the upper substrate 210. The bottom surface of the dielectric pattern 230 may be in contact with a top surface of the first upper dielectric layer 261. The dielectric pattern 230 may include a dielectric material.

The memory cell structure 240 may include cell gate structures 241, bit lines BL, a cell capacitor 243, cell capacitor connection contacts 244, and a cell capacitor connection conductive line 245. The memory cell structure 240 may be disposed in the cell block region CR. The memory cell structure 240 may be disposed in the sense amplifier region SAR, the second peripheral region PER2, and the sub-word line driver region SWDR. The memory cell structure 240 may be located at a level higher than that of the sensor amplifier and the sub-word line driver. The memory cell structure 240 may overlap in a third direction D3 with the sensor amplifier and the sub-word line driver. The memory cell structure 240 may overlap in the third direction D3 with the first transistor TR1.

The cell gate structures 241 may extend in the first direction D1 and may be arranged in the second direction D2. The cell gate structures 241 may be buried in the upper substrate 210.

The bit lines BL may extend in the second direction D2 and may be arranged in the first direction D1. The bit line BL may include a conductive material. The bit line BL may be disposed between the cell gate structure 241 and the cell capacitor 243.

The cell capacitor 243 may store data. The cell capacitor 243 may be electrically connected to the upper substrate 210 and the call capacitor connection contact 244.

The cell capacitor connection contacts 244 may connect the cell capacitor connection conductive line 245 to the cell capacitor 243. The cell capacitor connection contacts 244 and the cell capacitor connection conductive line 245 may include a conductive material. The cell capacitor 243 may be located at a level higher than that of the cell capacitor connection conductive line 245, the bit line BL may be located at a level higher than that of the cell capacitor 243, and the cell gate structure 241 may be located at a level higher than that of the bit line BL.

The power capacitor structure 250 may be located at the same level as that of the memory cell structure 240. The power capacitor structure 250 may include a first power capacitor connection conductive line 251, a power capacitor 252, power capacitor connection contacts 253, and a second power capacitor connection conductive line 254. The power capacitor structure 250 may be disposed in the first peripheral region PER1. At least a portion of the second transistors TR2 may overlap in the third direction D3 with the power capacitor structure 250.

The first power capacitor connection conductive line 251 may be located at the same level as that of the bit line BL. The power capacitor 252 may be located at the same level as that of the cell capacitor 243. The second power capacitor connection conductive line 254 may be located at the same level as that of the cell capacitor connection conductive line 245. The power capacitor 252 may be disposed between the first power capacitor connection conductive line 251 and the second power capacitor connection conductive line 254.

The power capacitor 252 may be electrically connected to the first power capacitor connection conductive line 251 and the second power capacitor connection conductive line 254. The power capacitor 252 may have a structure that is similar to that of the cell capacitor 243.

The power capacitor connection contact 253 may connect the second power capacitor connection conductive line 254 to the power capacitor 252. A conductive material may be included in the first and second power capacitor connection conductive lines 251 and 254 and the power capacitor connection contact 253.

First through vias 310, second through vias 320, third through vias 330, fourth through vias 340, a fifth through via 350, a sixth through via 360, and a seventh through via 370 may be provided. Each of the first to seventh through vias 310, 320, 330, 340, 350, 360, and 370 may be surrounded by the dielectric pattern 230. The first to seventh through vias 310, 320, 330, 340, 350, 360, and 370 may each have a width that decreases with decreasing distance from the lower substrate 110. The first to seventh through vias 310, 320, 330, 340, 350, 360, and 370 may each have a width that decreases as a level becomes lower. For example, the first to seventh through vias 310, 320, 330, 340, 350, 360, and 370 may each have a width in the second direction D2 that decreases as a level becomes lower. The first to seventh through vias 310, 320, 330, 340, 350, 360, and 370 may include a conductive material.

The first to seventh through vias 310, 320, 330, 340, 350, 360, and 370 may extend in the third direction D3. The third direction D3 may intersect the first direction D1 and the second direction D2. For example, the third direction D3 may be a vertical direction perpendicular to the first direction D1 and the second direction D2.

The first, second, and third through vias 310, 320, and 330 may be disposed in the extension region EXT. The second through via 320 may be disposed closer than the first through via 310 to the cell block region CR. The first through via 310 may be disposed closer than the third through via 330 to the cell block region CR. The fourth to seventh through vias 340, 350, 360, and 370 may be disposed in the first peripheral region PER1.

The first through via 310 may penetrate the upper substrate 210 and the upper dielectric structure 260, to thereby be connected to the first pad 153. The first through via 310 may have a bottom surface that is in contact with the top surface of the first pad 153. The first through via 310 may penetrate the upper substrate 210, the dielectric pattern 230, the first upper dielectric layer 261, the second upper dielectric layer 262, and the second lower dielectric layer 172.

The second through via 320 may be connected to the bit line BL. The second through via 320 may have a bottom surface that is in contact with a top surface of the bit line BL. The second through via 320 may penetrate the upper substrate 210 and the dielectric pattern 230.

The third through via 330 may penetrate the upper substrate 210 and the upper dielectric structure 260, thereby being connected to the second pad 154. The third through via 330 may have a bottom surface that is in contact with the top surface of the second pad 154. The third through via 330 may penetrate the upper substrate 210, the dielectric pattern 230, the first upper dielectric layer 261, the second upper dielectric layer 262, and the second lower dielectric layer 172.

The fourth through via 340 may penetrate the upper substrate 210 and the upper dielectric structure 260, thereby being connected to the third pad 163. The fourth through via 340 may have a bottom surface in contact with the top surface of the third pad 163. The fourth through via 340 may penetrate the upper substrate 210, the dielectric pattern 230, the first upper dielectric layer 261, the second upper dielectric layer 262, and the second lower dielectric layer 172.

The fifth through via 350 may penetrate the upper substrate 210 and the upper dielectric structure 260, thereby being connected to the fourth pad 164. The fifth through via 350 may have a bottom surface in contact with the top surface of the fourth pad 164. The fifth through via 350 may penetrate the upper substrate 210, the dielectric pattern 230, the first upper dielectric layer 261, the second upper dielectric layer 262, and the second lower dielectric layer 172.

The sixth through via 360 may be connected to the second power capacitor connection conductive line 254. The sixth through via 360 may have a bottom surface in contact with a top surface of the second power capacitor connection conductive line 254. The sixth through via 360 may penetrate the upper substrate 210 and the dielectric pattern 230.

The seventh through via 370 may be connected to the first power capacitor connection conductive line 251. The seventh through via 370 may have a bottom surface in contact with a top surface of the first power capacitor connection conductive line 251. The seventh through via 370 may penetrate the upper substrate 210 and the dielectric pattern 230.

The first to seventh through vias 310, 320, 330, 340, 350, 360, and 370 may have top surfaces that are located at the same level. The first, third, fourth, and fifth through vias 310, 330, 340, and 350 may have bottom surfaces that are located at the same level. The second and seventh through vias 320 and 370 may have bottom surfaces that are located at the same level. The level of the bottom surfaces of the first, third, fourth, and fifth through vias 310, 330, 340, and 350 may be lower than the level of the bottom surface of the sixth through via 360. The level of the bottom surface of the sixth through via 360 may be lower than the level of the bottom surfaces of the second and seventh through vias 320 and 370.

The connection structure 30 may include a connection dielectric structure 410, first connection conductive structures 420, and second connection conductive structures 430. The connection dielectric structure 410 may include a first connection dielectric layer 411 on the upper substrate 210 and a second connection dielectric layer 412 on the first connection dielectric layer 411. The first and second connection dielectric layers 411 and 412 may include different dielectric materials from each other. For example, the first connection dielectric layer 411 may include a SiO₂ layer, and the second connection dielectric layer 412 may include a silicon nitride layer.

In some embodiments, the first connection dielectric layer 411 may be a multiple dielectric layer including a plurality of dielectric layers. In some embodiments, the first and second connection dielectric layers 411 and 412 may include the same dielectric material. For example, the first and second connection dielectric layers 411 and 412 may include a SiO₂ layer.

The first connection conductive structures 420 and the second connection conductive structures 430 may be disposed in the first connection dielectric layer 411 of the connection dielectric structure 410. The first connection conductive structures 420 may include first connection contacts 421, first connection conductive lines 422, bit-line connection patterns 423, and first transistor connection patterns 424. A conductive material may be included in the first connection contacts 421, the first connection conductive lines 422, the bit-line connection patterns 423, and the first transistor connection patterns 424 of the first connection conductive structures 420.

The bit-line connection pattern 423 and the first transistor connection pattern 424 may be disposed on the extension region EXT. At least a portion of the first connection conductive lines 422 may extend from the extension region EXT toward the cell block region CR. The bit-line connection pattern 423 and the first transistor connection pattern 424 may be disposed at the bottom of the first connection conductive structures 420. The first connection contacts 421 and the first connection conductive lines 422 may be disposed at a level higher than that of the bit-line connection pattern 423 and the first transistor connection pattern 424.

The bit-line connection pattern 423 may be connected to the first through via 310 and the second through via 320. The bit-line connection pattern 423 may have a bottom surface in contact with the top surface of the first through via 310 and the top surface of the second through via 320. The bit line BL may be electrically connected to the first transistor TR1 through the second through via 320, the bit-line connection pattern 423, the first through via 310, the first pad 153, the first lower contact 151, and the first lower conductive line 152.

The first transistor connection pattern 424 may be located at the same level as that of the bit-line connection pattern 423. The first transistor connection pattern 424 may be connected to the third through via 330 and the first connection contact 421. The first transistor connection pattern 424 may have a top surface that is in contact with a bottom surface of the first connection contact 421. The first transistor connection pattern 424 may have a bottom surface that is in contact with the top surface of the third through via 330. The first connection conductive line 422 may be electrically connected to the first transistor TR1 through the first connection contact 421, the first transistor connection pattern 424, the third through via 330, the second pad 154, the first lower contact 151, and the first lower conductive line 152.

The bit-line connection pattern 423 and the first transistor connection pattern 424 may each have a thickness less than the thickness of the first connection conductive line 422. For example, a thickness in the third direction D3 of each of the bit-line connection pattern 423 and the first transistor connection pattern 424 may be less than a thickness in the third direction D3 of the first connection conductive line 422.

The second connection conductive structures 430 may include second connection contacts 431, second connection conductive lines 432, a second transistor connection pattern 433, a first power capacitor connection pattern 434, a second power capacitor connection pattern 435, and a terminal 436. A conductive material may be included in the second connection contacts 431, the second connection conductive lines 432, the second transistor connection pattern 433, the first power capacitor connection pattern 434, the second power capacitor connection pattern 435, and the terminal 436 of the second connection conductive structure 430. The first peripheral region PER1 may be provided thereon with the second connection contacts 431, the second connection conductive lines 432, the second transistor connection pattern 433, the first power capacitor connection pattern 434, the second power capacitor connection pattern 435, and the terminal 436 of the second connection conductive structure 430.

The second transistor connection pattern 433 and the first and second power capacitor connection patterns 434 and 435 may be disposed at lower portions of the second connection conductive structures 430. The second connection contact 431 and the second connection conductive lines 432 may be disposed at a level higher than that of the second transistor connection pattern 433 and the first and second power capacitor connection patterns 434 and 435. The terminal 436 may be located at a level higher than that of the second connection contacts 431 and the second connection conductive lines 432. The semiconductor device 1 may be electrically connected through the terminal 436 to an external apparatus.

The second transistor connection pattern 433 may be connected to the fourth through via 340 and the second connection contact 431. The second transistor connection pattern 433 may have a top surface that is in contact with a bottom surface of the second connection contact 431. The second transistor connection pattern 433 may have a bottom surface that is in contact with a top surface of the fourth through via 340. The terminal 436 may be electrically connected to the second transistor TR2 through the second connection conductive line 432, the second connection contact 431, the second transistor connection pattern 433, the fourth through via 340, the third pad 163, the second lower contact 161, and the second lower conductive line 162.

The first power capacitor connection pattern 434 may be connected to the fifth through via 350 and the sixth through via 360. The first power capacitor connection pattern 434 may have a bottom surface that is in contact with a top surface of the fifth through via 350 and the top surface of the sixth through via 360. The second power capacitor connection conductive line 254 may be electrically connected to the second transistor TR2 through the sixth through via 360, the first power capacitor connection pattern 434, the fifth through via 350, the fourth pad 164, the second lower contact 161, and the second lower conductive line 162.

The second power capacitor connection pattern 435 may be connected to the seventh through via 370. The second power capacitor connection pattern 435 may have a bottom surface in contact with the top surface of the seventh through via 370. The second power capacitor connection pattern 435 may be electrically connected through the seventh through via 370 to the first power capacitor connection conductive line 251.

The terminal 436 may penetrate the second connection dielectric layer 412. The terminal 436 may be upwardly exposed from the second connection dielectric layer 412.

The second transistor connection pattern 433 and the first and second power capacitor connection patterns 434 and 435 may be located at the same level as that of the bit-line connection pattern 423 and the first transistor connection pattern 424.

The second transistor connection pattern 433 and the first and second power capacitor connection patterns 434 and 435 may each have a thickness less than that of the second connection conductive line 432. For example, a thickness in the third direction D3 of each of the second transistor connection pattern 433 and the first and second power capacitor connection patterns 434 and 435 may be less than a thickness in the third direction D3 of the second connection conductive line 432.

Referring to FIG. 1C, the first pads 153 may be disposed in a zigzag fashion. The first pads 153 adjacent in the first direction D1 may be disposed offset from each other in the second direction D2. When the first pads 153 are disposed in a zigzag fashion, even when the first pads 153 have a relatively large width, the first pads 153 may be prevented from being in contact with each other.

In a semiconductor device according to some embodiments, transistors that constitute a sense amplifier and a sub-word line driver may be disposed to overlap a memory cell structure. Therefore, it may be possible to provide a relatively large size for the transistors that constitute the sense amplifier and the sub-word line driver, in order to reduce the cost of fabrication of the transistors, and to improve the electrical properties of the transistors. In addition, integration of the semiconductor device may be improved to allow the semiconductor device to have a relatively small size.

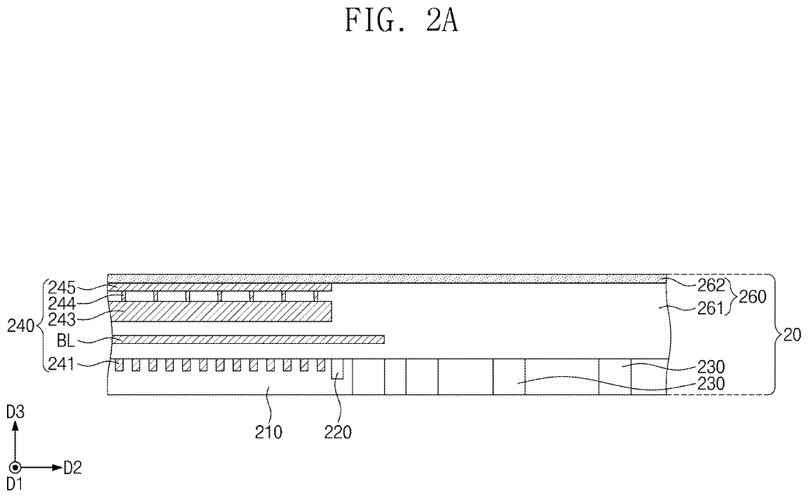

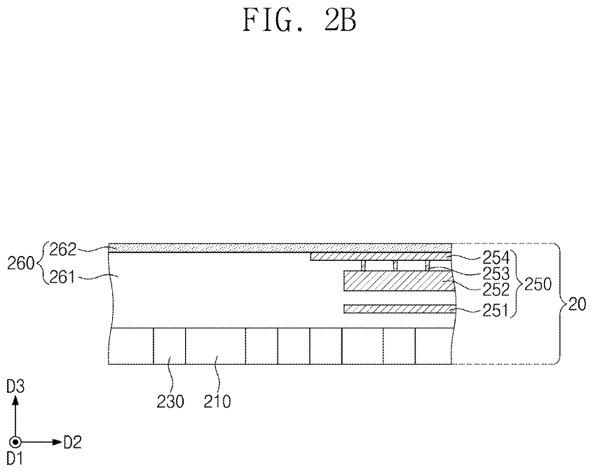

FIGS. 2A, 2B, 3A, 3B, 4A, 4B, 5A, and 5B illustrate cross-sectional views showing a method of fabricating a semiconductor device according to some embodiments. FIGS. 2A, 3A, 4A, and 5A may correspond to FIG. 1D. FIGS. 2B, 3B, 4B, and 5B may correspond to FIG. 1E.

Referring to FIGS. 2A and 2B, an upper bonding structure 20 may be formed. Dielectric patterns 230 may be formed to penetrate an upper substrate 210. A second device isolation layer 220 may be formed in the upper substrate 210.

A memory cell structure 240 may be formed on the upper substrate 210. A power capacitor structure 250 may be formed on the upper substrate 210. An upper dielectric structure 260 may be formed to cover the memory cell structure 240 and the power capacitor structure 250.

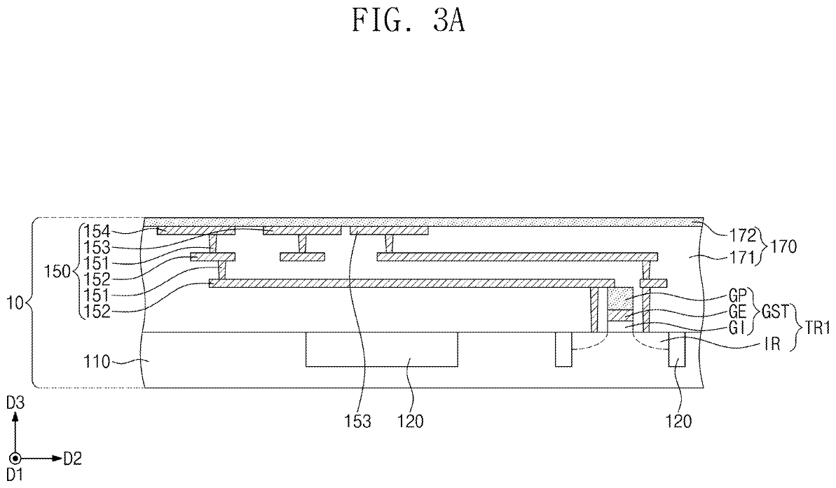

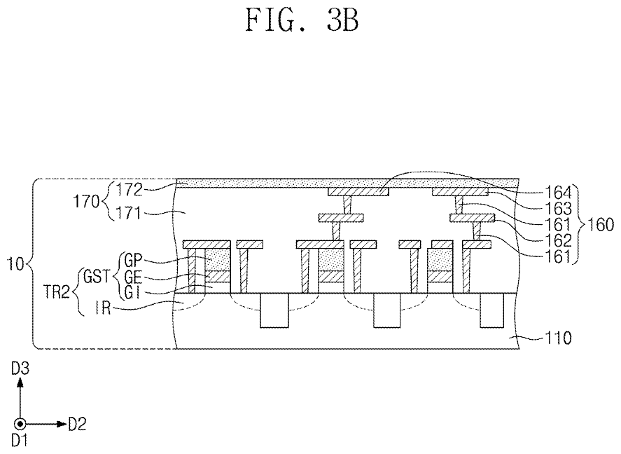

Referring to FIGS. 3A and 3B, a lower bonding structure 10 may be formed. First device isolation layers 120 may be formed in a lower substrate 110. First transistors TR1 and second transistors TR2 may be formed on a lower substrate 110.

First lower conductive structures 150, second lower conductive structures 160, and a lower dielectric structure 170 may be formed on the lower substrate 110.

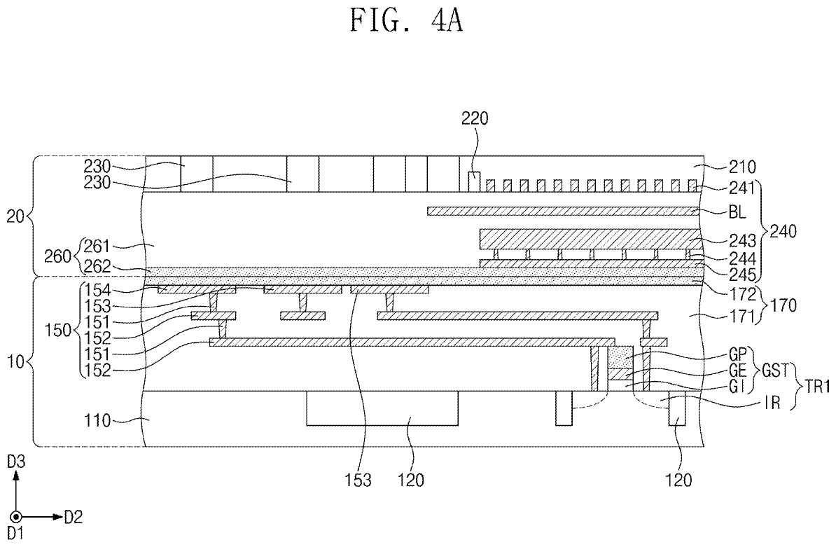

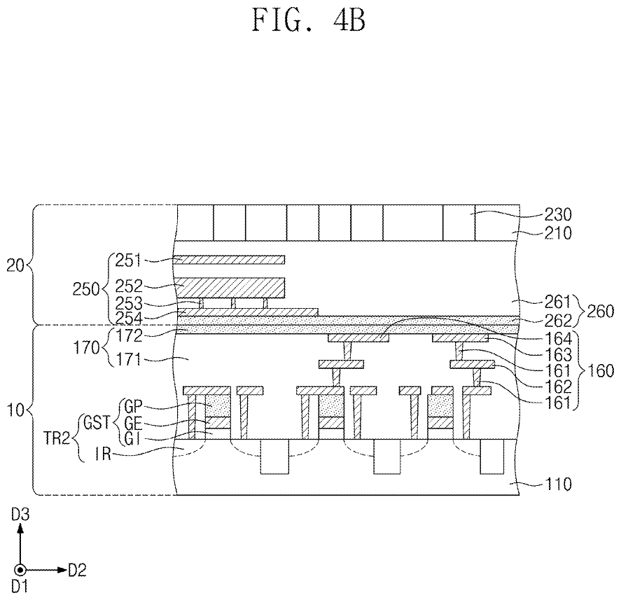

Referring to FIGS. 4A and 4B, the upper bonding structure 20 may be turned upside down and bonded to the lower bonding structure 10. A second lower dielectric layer 172 of the lower dielectric structure 170 may be bonded to a second upper dielectric layer 262 of the upper dielectric structure 260.

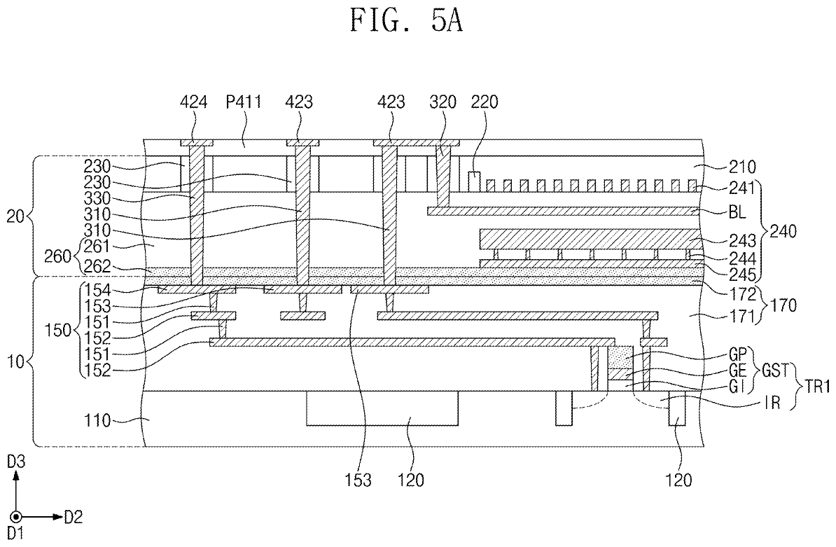

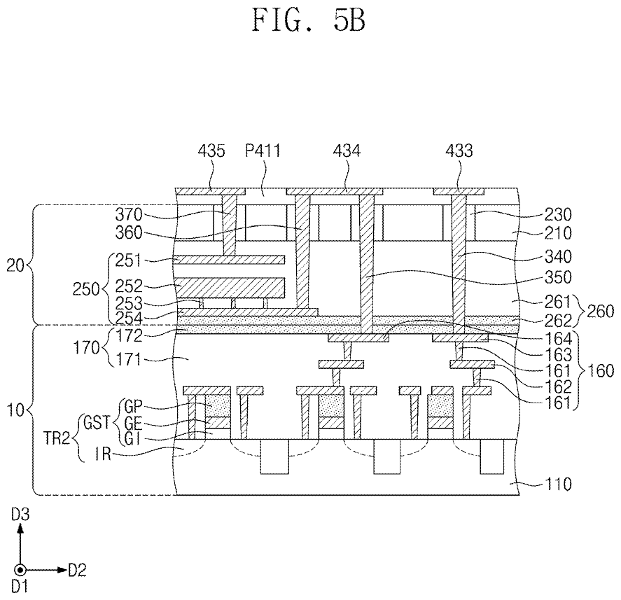

Referring to FIGS. 5A and 5B, first to seventh through vias 310, 320, 330, 340, 350, 360, and 370 may be formed. A lower part P411 of a first connection dielectric layer, bit-line connection patterns 423, a first transistor connection pattern 424, a second transistor connection pattern 433, a first power capacitor connection pattern 434, and a second power capacitor connection pattern 435 may also be formed.

The formation of the first to seventh through vias 310, 320, 330, 340, 350, 360, and 370 may include forming through holes that penetrate the upper substrate 210 and filling the through holes with a conductive material.

Referring to FIGS. 1D and 1E, a connection dielectric structure 410 may be formed on the upper substrate 210. First connection conductive structures 420 and second connection conductive structures 430 may be formed in the connection dielectric structure 410.

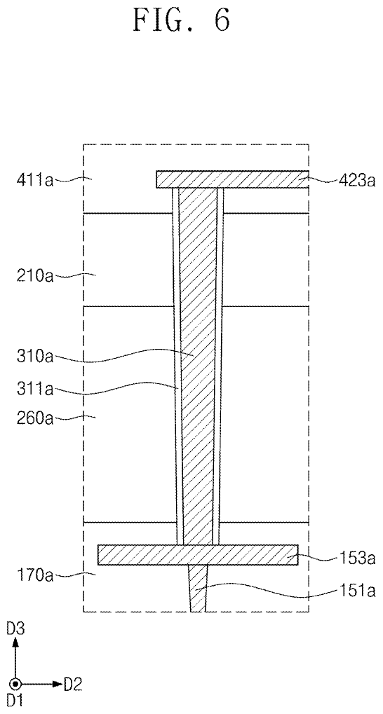

FIG. 6 illustrates an enlarged cross-sectional view showing a semiconductor device according to some embodiments.

Referring to FIG. 6, in a semiconductor device, a lower dielectric structure 170a and an upper dielectric structure 260a may include the same dielectric material. For example, the lower dielectric structure 170a and the upper dielectric structure 260a may include a SiO₂ layer. An upper substrate 210a may be provided on the upper dielectric structure 260a. A connection dielectric layer 411a may be provided on the upper substrate 210a.

A bit-line connection pattern 423a may be provided in the connection dielectric layer 411a. The bit-line connection pattern 423a may be electrically connected to a bit line of a memory cell structure.

A pad 153a and a lower contact 151a may be provided in the lower dielectric structure 170a. The pad 153a and the lower contact 151a may be electrically connected to a transistor that constitutes a sense amplifier.

A through via 310a and a through dielectric layer 311a may be provided to penetrate the upper substrate 210a and the upper dielectric structure 260a. The through via 310a may connect the bit-line connection pattern 423a to the pad 153a. The through dielectric layer 311a may have a top surface that is in contact with a bottom surface of the bit-line connection pattern 423a. The through dielectric layer 311a may have a bottom surface that is in contact with a top surface of the pad 153a. The through dielectric layer 311a may include a dielectric material.

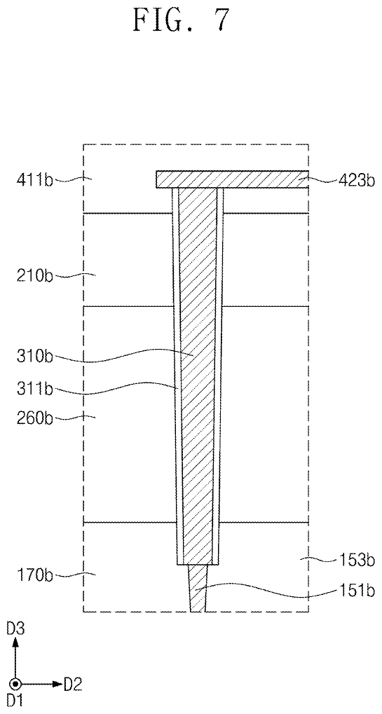

FIG. 7 illustrates an enlarged cross-sectional view showing a semiconductor device according to some embodiments.

Referring to FIG. 7, a semiconductor device may include a lower dielectric structure 170b, an upper dielectric structure 260b on the lower dielectric structure 170b, an upper substrate 210b on the upper dielectric structure 260b, and a connection dielectric layer 411b on the upper substrate 210b.

A bit-line connection pattern 423b may be provided in the connection dielectric layer 411b. A lower contact 151b may be provided in the lower dielectric structure 170b. A through via 310b may penetrate the upper substrate 210b and the upper dielectric structure 260b to connect the bit-line connection pattern 423b to the lower contact 151b. The lower contact 151b may have a top surface in contact with a bottom surface of the through via 310b. The top surface of the lower contact 151b may have a width that is less than the width of the bottom surface of the through via 310b. A through dielectric layer 311b may be provided to surround the through via 310b.

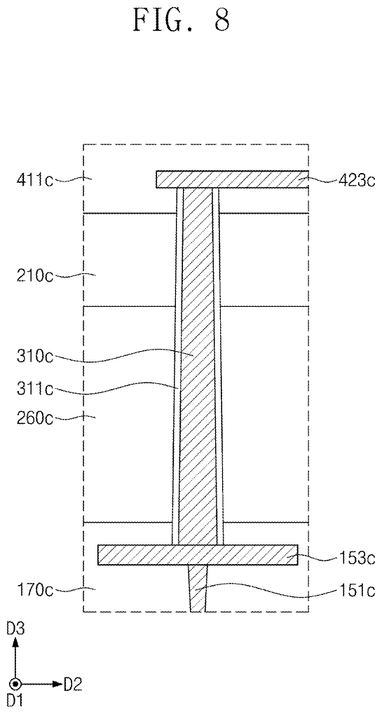

FIG. 8 illustrates an enlarged cross-sectional view showing a semiconductor device according to some embodiments.

Referring to FIG. 8, a semiconductor device may include a lower dielectric structure 170c, an upper dielectric structure 260c on the lower dielectric structure 170c, an upper substrate 210c on the upper dielectric structure 260c, and a connection dielectric layer 411c on the upper substrate 210c.

A bit-line connection pattern 423c may be provided in the connection dielectric layer 411c. A lower contact 151c and a pad 153c may be provided in the lower dielectric structure 170c. A through via 310c may penetrate the upper substrate 210c and the upper dielectric structure 260c to connect the bit-line connection pattern 423c to the pad 153c. The through via 310c may have a width that increases as a level of the through via 310c becomes lower, for example as a distance from the bit-line connection pattern increases. For example, a width in the second direction D2 of the through via 310c may increase as a level of the through via 310c becomes lower. A through dielectric layer 311c may be provided to surround the through via 310c.

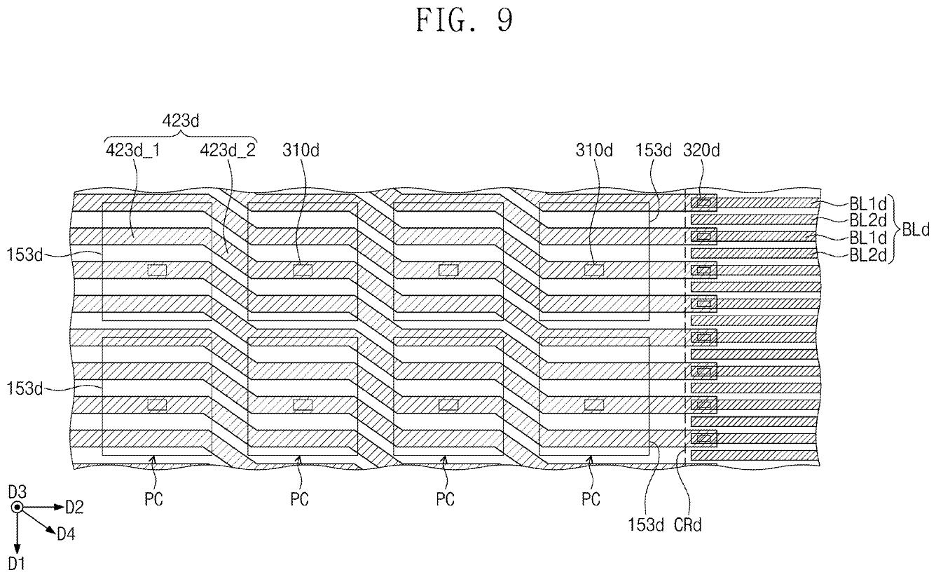

FIG. 9 illustrates a plan view showing a bit-line connection structure of a semiconductor device according to some embodiments.

Referring to FIG. 9, one cell block region CRd of a semiconductor device may include bit lines BLd including first bit lines BL1d and second bit lines BL2d that are alternately arranged along the first direction D1.

The first bit lines BL1d may be electrically connected to pads 153d that are disposed adjacent to a first side of the cell block region CRd. The second bit lines BL2d may be electrically connected to pads that are disposed adjacent to a second side of the cell block region CRd, which second side stands opposite to each other.

The pad 153d may have a tetragonal shape when viewed in a plan view. The pad 153d may be electrically connected to the first bit line BL1d through a first through via 310d, a bit-line connection pattern 423d, and a second through via 320d.

The pads 153d that are adjacent in the second direction D2 may completely overlap each other in the second direction D2. The pads 153d that are adjacent in the second direction D2 may have their sidewalls parallel to the second direction D2 The sidewalls of the pads 153d may be disposed on a straight line that extends in the second direction D2.

One pad column PC may be provided by the pads 153d that are arranged in the first direction D1. The number of pad columns PC may be related to the number of bit lines BLd that overlap in the second direction D2 with the one pad 153d. The number of pad columns PC may be about ½ of the number of bit lines BL that overlap in the second direction D2 with the one pad 153d. For example, when eight bit lines BLd are provided to overlap in the second direction D2 with the one pad 153d, the number of pad columns PC may be four.

In some embodiments, when a pitch in the first direction D1 of the pads 153d is an integer number of times (N1 times) a pitch in the first direction D1 of the bit lines BLd, the number of pad columns PC may be N1×0.5.

In some embodiments, when a distance between centers of neighboring pads 153d is an integer number of times (N2 times) a pitch in the first direction D1 of the bit lines BLd, the number of pad columns PC may be N2×0.5.

In some embodiments, a pitch in the first direction D1 of the pads 153d is an integer number of times (N3 times) a pitch in the first direction D1 of the bit lines BLd, a pitch in the first direction D1 of a unit sense amplifier may be an integer number of times (N4 times) a pitch in the first direction D1 of the bit lines BLd. In this case, N4 may be an integer number of times (N5 times) N3, and 0.5×N4 numbers of unit sense amplifiers may be arranged in the second direction D2 on a sense amplifier region.

The bit-line connection pattern 423d may include extension parts 423d_1 and connection parts 423d_2 that are disposed alternately with each other. The extension part 423d_1 may be a portion that extends in the second direction D2. The connection part 423d_2 may be a portion that extends in a fourth direction D4. The fourth direction D4 may intersect the first direction D1, the second direction D2, and the third direction D3. For example, the fourth direction D4 may be a horizontal direction perpendicular to the third direction D3.

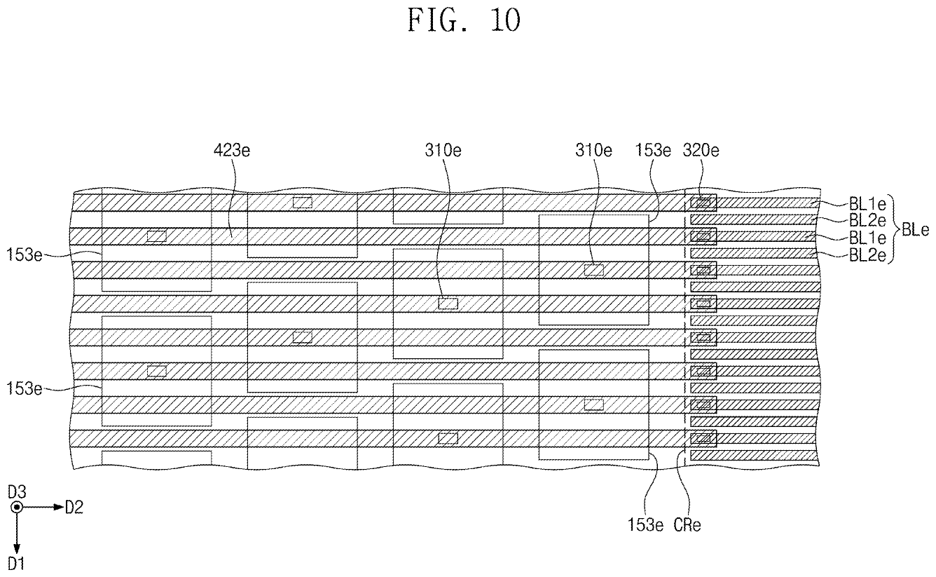

FIG. 10 illustrates a plan view showing a bit-line connection structure of a semiconductor device according to some embodiments.

Referring to FIG. 10, bit lines BLe included in one cell block region CRe of a semiconductor device may include first bit lines BL1e and second bit lines BL2e that are alternately arranged along the first direction D1.

A pad 153e may have a tetragonal shape when viewed in a plan view. The pad 153e may be electrically connected to the first bit line BL1e through the first through via 310e, a bit-line connection pattern 423e, and a second through via 320e.

A plurality of pads 153e that are adjacent in the second direction D2 may partially overlap each other in the second direction D2. The pads 153e that are adjacent in the second direction D2 may have their sidewalls parallel to the second direction D2, and the sidewalls of the pads 153e may not be disposed on a straight line that extends in the second direction D2. The pads 153e that are adjacent in the second direction D2 may be disposed to be offset from each other in the first direction D1. For example, the pads 153e that are adjacent in the second direction D2 may be offset in the first direction D1 from each other as much as twice the pitch in the first direction D1 of the bit lines BLe. The bit-line connection pattern 423e may extend in the second direction D2.

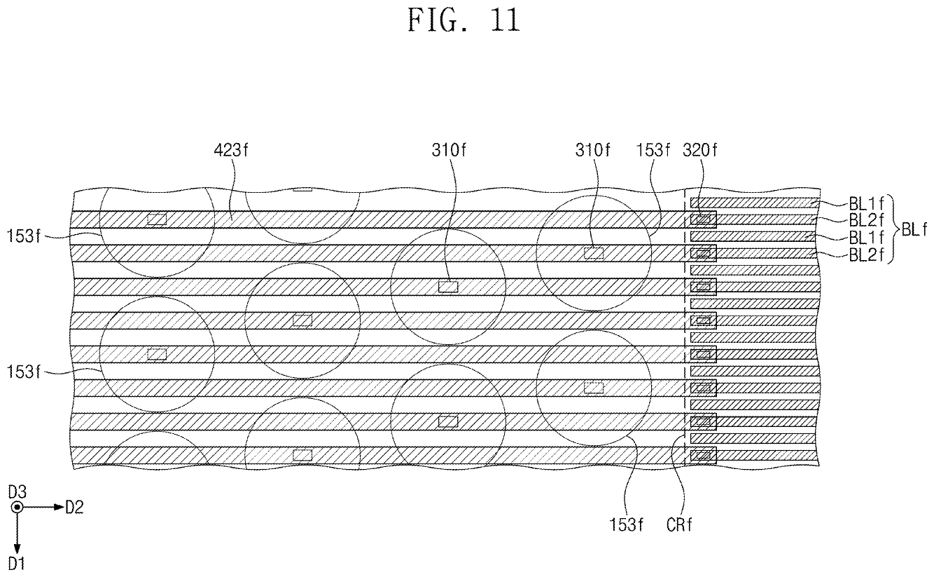

FIG. 11 illustrates a plan view showing a bit-line connection structure of a semiconductor device according to some embodiments.

Referring to FIG. 11, bit lines BLf included in one cell block region CRf of a semiconductor device may include first bit lines BL1f and second bit lines BL2f that are alternately arranged along the first direction D1.

A pad 153f may have a circular shape when viewed in plan. The pad 153f may be electrically connected to the first bit line BL If through a first through via 310f, a bit-line connection pattern 423f and a second through via 320f.

A plurality of pads 153f that are adjacent in the second direction D2 may partially overlap each other in the second direction D2. The pads 153f that are adjacent in the second direction D2 may be disposed offset from each other in the first direction D1. For example, the pads 153f that are adjacent in the second direction D2 may be offset in the first direction D1 from each other as much as twice a pitch in the first direction D1 of the bit lines BLf. The bit-line connection pattern 423f may extend in the second direction D2.

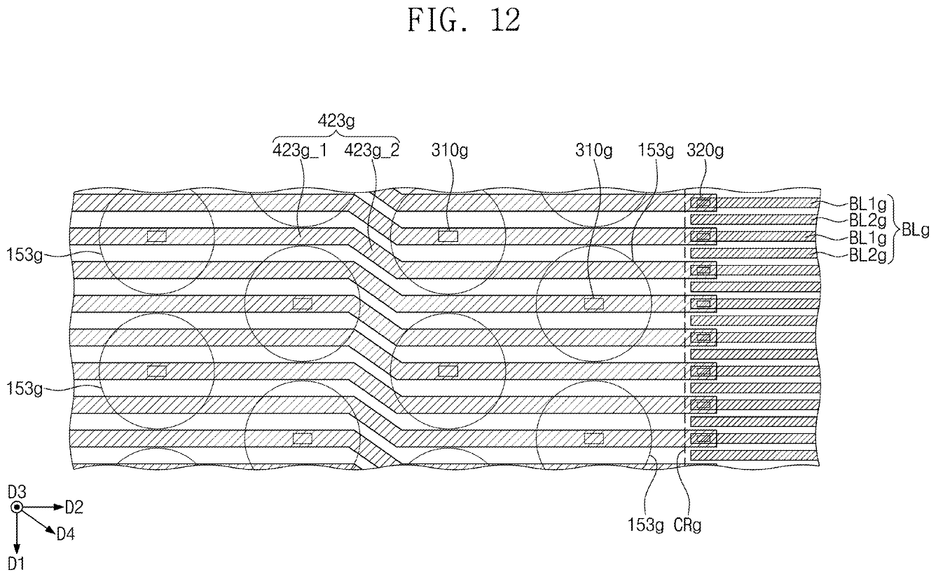

FIG. 12 illustrates a plan view showing a bit-line connection structure of a semiconductor device according to some embodiments.

Referring to FIG. 12, bit lines BLg included in one cell block region CRg of a semiconductor device may include first bit lines BL1g and second bit lines BL2g that are alternately arranged along the first direction D1.

A pad 153g may have a circular shape when viewed in plan. The pad 153g may be electrically connected to the first bit line BL1g through a first through via 310g, a bit-line connection pattern 423g, and a second through via 320g.

The bit-line connection pattern 423g may include extension parts 423g_1 and connection parts 423g_2. The extension part 423g_1 may extend in the second direction D2. The connection part 423g_2 may extend in the fourth direction D4 to connect two extension parts 423g_1 to each other.

A plurality of pads 153g that are adjacent in the second direction D2 may partially overlap each other in the second direction D2. The pads 153g that are adjacent in the second direction D2 may be disposed offset from each other in the first direction D1. For example, the pads 153g that are adjacent in the second direction D2 may be offset in the first direction D1 from each other as much as four times a pitch in the first direction D1 of the bit lines BLg.

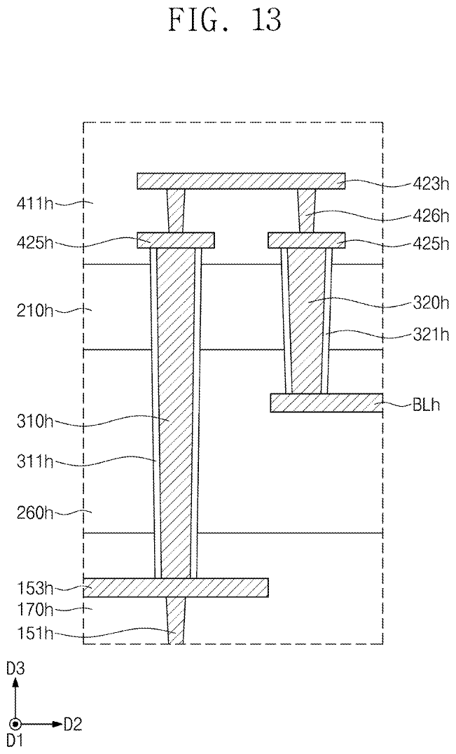

FIG. 13 illustrates an enlarged cross-sectional view showing a semiconductor device according to some embodiments.

Referring to FIG. 13, a semiconductor device may include a lower dielectric structure 170h, an upper dielectric structure 260h on the lower dielectric structure 170h, an upper substrate 210h on the upper dielectric structure 260h, and a connection dielectric layer 411h on the upper substrate 210h.

The connection dielectric layer 411h may be provided therein with via connection patterns 425h, via connection contacts 426h, and a bit-line connection pattern 423h. A lower contact 151h and a pad 153h may be provided in the lower dielectric structure 170h.

A first through via 310h may penetrate the upper substrate 210h and the upper dielectric structure 260h to connect the via connection pattern 425h to the pad 153h. A second through via 320h may penetrate the upper substrate 210h to connect a bit line BLh to the via connection pattern 425h. The via connection contact 426h may connect the via connection pattern 425h to the bit-line connection pattern 423h. The bit-line connection pattern 423h may connect the via connection contacts 426h to each other. A first through dielectric layer 311h may be provided to surround the first through via 310h, and a second through dielectric layer 321h may be provided to surround the second through via 320h.

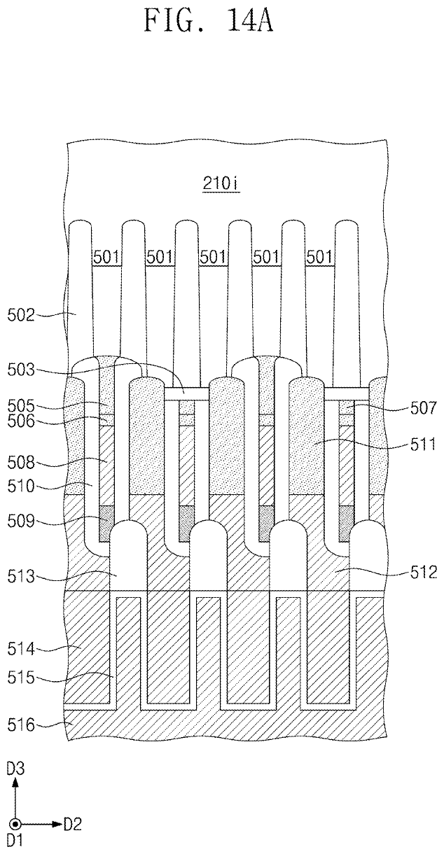

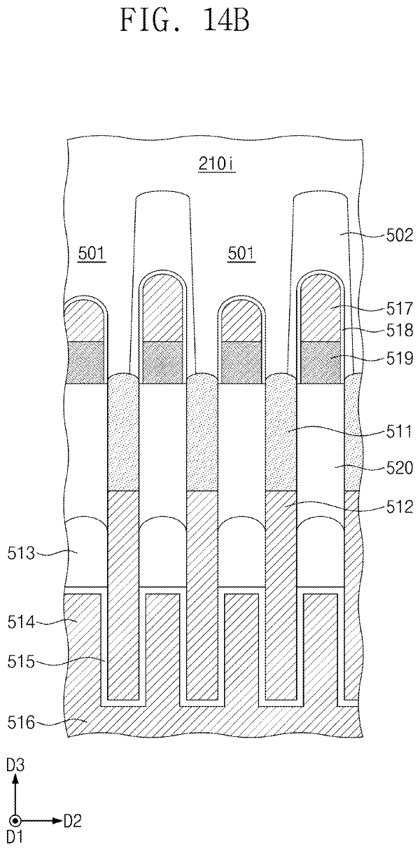

FIGS. 14A and 14B illustrate cross-sectional views showing a memory cell structure according to some embodiments.

Referring to FIGS. 14A and 14B, a memory cell structure may be provided that is connected to an upper substrate 210i. The memory cell structure may include active patterns 501, cell device isolation layers 502, cell dielectric layers 503, bit-line contacts 505, first conductive layers 507, second conductive layers 506, third conductive layers 508, bit-line capping layers 509, bit-line spacers 510, node contacts 511, landing pads 512, a landing pad isolation layer 513, first cell capacitor electrodes 514, a cell capacitor dielectric layer 515, a second cell capacitor electrode 516, cell gate electrodes 517, cell gate dielectric layers 518, cell gate capping layers 519, and dielectric fences 520.

The upper substrate 210i may include lower portions that protrude in a direction reverse to the third direction D3, and the active patterns 501 may be defined to indicate the protruding lower portions of the upper substrate 210i. The active patterns 501 may be spaced apart from each other.

The cell device isolation layers 502 may be provided in a space between the active patterns 501. The cell device isolation layers 502 may be provided in the upper substrate 210i. The active patterns 501 may be defined by the cell device isolation layers 502. The cell device isolation layer 502 may include a dielectric material.

A gate structure may be provided that includes the cell gate electrode 517, the cell gate dielectric layer 518, and the cell gate capping layer 519. A plurality of gate structures may extend in the first direction D1. The gate structures may be arranged in the second direction D2. The gate structure may be a buried gate structure that is buried in the active patterns 501 and the cell device isolation layer 502. The cell gate dielectric layer 518 and the cell gate capping layer 519 may include a dielectric material. The cell gate electrode 517 may include a conductive material.

The cell dielectric layers 503 may be provided on bottom surfaces of the cell device isolation layers 502 and the gate structures. The cell dielectric layer 503 may include a dielectric material. In some embodiments, the cell dielectric layer 503 may include a plurality of dielectric layers.

Bit-line structures may be provided which extend in the second direction D2. The bit-line structures may be arranged in the first direction D1. The bit-line structure may include bit-line contacts 505, first conductive layers 507, a second conductive layer 506, a third conductive layer 508, a bit-line capping layer 509, and a bit-line spacer 510.

The bit-line contacts 505 and the first conductive layers 507 of the bit-line structure may be alternately disposed along the second direction D2. The bit-line contact 505 may be connected to the active pattern 501. The first conductive layer 507 may be provided on a bottom surface of the cell dielectric layer 503. In some embodiments, the bit-line contacts 505 and the first conductive layers 507 included in one bit-line structure may be connected into a single unitary structure with no boundary therebetween.

The second conductive layer 506 may be provided on bottom surfaces of the first conductive layers 507 and the bit-line contacts 505. The third conductive layer 508 may be provided on a bottom surface of the second conductive layer 506. The bit-line capping layer 509 may be provided on a bottom surface of the third conductive layer 508. A conductive material may be included in the bit-line contact 505, the first conductive layer 507, the second conductive layer 506, and the third conductive layer 508. The bit-line capping layer 509 may include a dielectric material.

The bit-line spacer 510 may cover a bottom surface and a sidewall of the bit-line capping layer 509, sidewalls of the first, second, and third conductive layers 507, 506, and 508, and sidewalls of the bit-line contacts 505. The bit-line spacer 510 may include a dielectric material. In some embodiments, the bit-line spacer 510 may include a plurality of dielectric layers.

The node contact 511 may be connected to the active pattern 501. The node contact 511 may be provided between neighboring bit-line structures. The node contact 511 may include a conductive material. For example, the node contact 511 may include polysilicon.

The landing pad 512 may be provided on a bottom surface of the node contact 511. The landing pad 512 may include a conductive material. In some embodiments, a metal silicide layer and a barrier layer may be provided between the node contact 511 and the landing pad 512.

The dielectric fence 520 may be provided on a bottom surface of the cell gate capping layer 519. The dielectric fence 520 may be provided between the node contacts 511 that are adjacent to each other in the second direction D2. The dielectric fence 520 may include a dielectric material.

The landing pad isolation layer 513 may be provided on a bottom surface of the dielectric fence 520. The landing pad isolation layer 513 may separate the landing pads 512 from each other. The landing pad isolation layer 513 may surround the landing pad 512. The landing pad isolation layer 513 may include a dielectric material.

A cell capacitor may be constituted by the first cell capacitor electrode 514, the cell capacitor dielectric layer 515, and the second cell capacitor electrode 516. The cell capacitor dielectric layer 515 may be provided between the first cell capacitor electrode 514 and the second cell capacitor electrode 516. The first and second cell capacitor electrodes 514 and 516 may include a conductive material. The cell capacitor dielectric layer 515 may include a dielectric material. A semiconductor device may be a dynamic random access memory (DRAM) including the cell capacitor.

In some embodiments, the memory cell structure may include a magnetic tunnel junction pattern instead of the cell capacitor. In this case, the semiconductor device may be a magnetic tunnel junction pattern (MRAM). In some embodiments, the memory cell structure may include a phase change material or a variable resistance material instead of the cell capacitor. In this case, the semiconductor device may be a phase change random access memory (PRAM) or a resistive random access memory (ReRAM). In some embodiments, various structures and/or materials capable of storing data may be provided instead of the cell capacitor.

In some embodiments, the memory cell structure may include a vertical channel transistor (VCT) in which a channel extends in the third direction D3.

In a semiconductor device according to some embodiments, as sense amplifiers overlap a memory cell structure, it may be possible to reduce a size of a unit sense amplifier, to decrease cost of fabrication for the sense amplifier, and to improve electrical properties of the sense amplifier.

By way of summation and review may provide a semiconductor device with electrical properties that are increased

Although some embodiments have been discussed with reference to accompanying figures, it will be understood that various changes in form and details may be made therein without departing from the spirit and scope thereof. It therefore will be understood that the embodiments described above are just illustrative but not limitative in all aspects.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor device, comprising:
a lower bonding structure that includes a lower substrate, a lower dielectric structure on the lower substrate, and a transistor between the lower substrate and the lower dielectric structure;
an upper bonding structure that includes an upper dielectric structure on the lower dielectric structure, an upper substrate on the upper dielectric structure, and a memory cell structure between the upper substrate and the upper dielectric structure;
a connection structure on the upper bonding structure; and
a first through via that electrically connects the transistor to the memory cell structure, wherein:
the transistor overlaps the memory cell structure, and
the first through via penetrates the upper substrate and the upper dielectric structure.

2. The semiconductor device as claimed in claim 1, wherein the transistor constitutes a sense amplifier.

3. The semiconductor device as claimed in claim 1, wherein:
the lower bonding structure includes lower conductive structures that electrically connect the first through via to the transistor,
the lower conductive structures include a pad at top of the lower conductive structures, and
a top surface of the pad is in contact with a bottom surface of the first through via.

4. The semiconductor device as claimed in claim 1, wherein the upper bonding structure further includes a dielectric pattern that surrounds the first through via, and the dielectric pattern is in the upper substrate.

5. The semiconductor device as claimed in claim 1, wherein:
the memory cell structure includes a bit line, and
the first through via electrically connects the bit line to the transistor.

6. The semiconductor device as claimed in claim 5, wherein:
the connection structure includes a bit-line connection pattern in contact with a top surface of the first through via,
the semiconductor device further includes a second through via in contact with the bit-line connection pattern and the bit line, and
the second through via penetrates the upper substrate.

7. The semiconductor device as claimed in claim 6, wherein:
the connection structure includes a connection conductive structure at a level higher than a level of the bit-line connection pattern, and
a thickness of the connection conductive structure is greater than a thickness of the bit-line connection pattern.

8. The semiconductor device as claimed in claim 7, further including a third through via that electrically connects the connection conductive structure to the transistor, wherein the third through via penetrates the upper substrate.

9. A semiconductor device, comprising:
a lower bonding structure that includes a lower substrate, a lower dielectric structure on the lower substrate, a lower conductive structure in the lower dielectric structure, and a first transistor between the lower substrate and the lower dielectric structure;
an upper bonding structure that includes an upper dielectric structure on the lower dielectric structure, an upper substrate on the upper dielectric structure, and a memory cell structure between the upper substrate and the upper dielectric structure, the memory cell structure including a bit line;
a first through via that penetrates the upper substrate and the upper dielectric structure and is in contact with the lower conductive structure;
a second through via that penetrates the upper substrate and is in contact with the bit line; and
a bit-line connection pattern in contact with the first through via and the second through via.

10. The semiconductor device as claimed in claim 9, wherein the first transistor overlaps the memory cell structure.

11. The semiconductor device as claimed in claim 9, further including a connection conductive line at a level higher than a level of the bit-line connection pattern,
wherein a thickness of the connection conductive line is greater than a thickness of the bit-line connection pattern.

12. The semiconductor device as claimed in claim 9, further including a through dielectric layer that surrounds the first through via,
wherein the through dielectric layer penetrates the upper substrate and the upper dielectric structure.

13. The semiconductor device as claimed in claim 9, wherein each of the first through via and the second through via has a width that decreases with decreasing distance from the lower substrate.

14. The semiconductor device as claimed in claim 9, wherein each of the first through via and the second through via has a width that decreases as a level becomes lower.

15. The semiconductor device as claimed in claim 9, wherein:
the lower conductive structure includes a lower contact in contact with the first through via, and
a top surface of the lower contact has a width less than a width of a bottom surface of the first through via.

16. The semiconductor device as claimed in claim 9, wherein:
the lower bonding structure further includes a second transistor between the upper substrate and the lower dielectric structure, and
the upper bonding structure further includes a power capacitor in the upper dielectric structure.

17. The semiconductor device as claimed in claim 16, further including a third through via that electrically connects the second transistor to the power capacitor.

18. The semiconductor device as claimed in claim 16, wherein:
the memory cell structure further includes a cell capacitor, and
the power capacitor is at a level the same as a level of the cell capacitor.

19. A semiconductor device, comprising:
a lower substrate;
a lower dielectric structure on the lower substrate;
a transistor between the lower substrate and the lower dielectric structure;
a lower conductive structure in the lower dielectric structure and connected to the transistor;
an upper dielectric structure on the lower dielectric structure;
an upper substrate on the upper dielectric structure;
a memory cell structure between the upper substrate and the upper dielectric structure, the memory cell structure including a bit line;
a connection dielectric structure on the upper substrate;
a bit-line connection pattern in the connection dielectric structure;
a first through via that connects the lower conductive structure to the bit-line connection pattern and penetrates the upper substrate and the upper dielectric structure; and
a second through via that connects the bit line to the bit-line connection pattern and penetrates the upper substrate,
wherein the transistor overlaps the memory cell structure.

20. The semiconductor device as claimed in claim 19, wherein: the bit-line connection pattern includes:
an extension part that extends in a first direction; and
a connection part that extends in a second direction intersecting the first direction.
